(19) United States
(12) Patent Application Publication
(10) Pub. No.: US 2020/0150170 A1
(43) Pub. Date: May 14, 2020

(54) MEASUREMENT SYSTEM AND METHOD FOR OVER-THE-AIR MEASUREMENTS

(71) Applicant: Rohde & Schwarz GmbH & Co. KG, Munich (DE)

(72) Inventors: Corbett ROWELL, Munich (DE); Daniel MARKERT, Deggendorf (DE); Ralf-Benjamin MEISSNER, Gilching (DE)

(21) Appl. No.: 16/186,061

(22) Filed: Nov. 9, 2018

(51) Int. Cl. G01R 29/10

(52) U.S. Cl. CPC G01R 29/105

(57) ABSTRACT

A measurement system for over-the-air measurements is provided. The measurement system comprises a device under test, at least one antenna, a positioner for positioning the device under test, wherein the positioner comprises at least one rotational axis, and a measurement equipment connected to the at least one antenna. In this context, the at least one rotational axis includes a common interface for different measurement setups.

### TECHNICAL FIELD

The invention relates to a measurement system and a corresponding measurement method for over-the-air measurements with special respect to switching between different measurement setups in a highly efficient manner due to an universal mount.

### BACKGROUND

Generally, in times of an increasing number of applications providing wireless communication capabilities, there is a growing need of a measurement system and a corresponding measurement method especially for verifying correct functioning of said applications in a highly efficient manner with special respect to a plurality of different measurement setups.

US 2008/0087211 A1 relates generally to accessories and the mounting of accessories to a vehicle, such as a boat, or any fixed object. More particularly, said document relates to an universal mount designed to accept a wide variety of accessories, which is capable of releasably securing the accessory to a surface and locking the accessory in a rotational orientation as desired. As it can be seen, said universal mount is exclusively used with a vehicle, especially a boat or the gunnel thereof, which leads to fact that said mount cannot be applied in the context of over-the-air measurements or measurement systems and methods therefor.

Accordingly, there is a need to provide a measurement system and a corresponding measurement method for over-the-air measurements with special respect to switching between different measurement setups in a highly efficient manner due to an universal mount.

### SOME EXAMPLE EMBODIMENTS

Embodiments of the present invention advantageously address the foregoing requirements and needs, as well as others, by providing a measurement system and a corresponding measurement method for over-the-air measurements with special respect to switching between different measurement setups in a highly efficient manner due to an universal mount.

According to a first aspect of the invention, a measurement system for over-the-air measurements is provided. Said measurement system comprises a device under test, at least one antenna, a positioner for positioning the device under test, wherein the positioner comprises at least one rotational axis, and a measurement equipment connected to the at least one antenna. In this context, the at least one rotational axis comprises a common interface for different measurement setups. Advantageously, this allows for switching between different measurement setups in a highly efficient manner. Further advantageously, the measurement system can be used for both direct and indirect far-field systems, wherein the respective planar wave especially originates from above the device under test.

According to a first preferred implementation form of the first aspect of the invention, the at least one antenna is adapted to create at least one electromagnetic wave along at least one vertical axis with respect to the device under test. Advantageously, for instance, measurement efficiency can be increased.

According to a second preferred implementation form of the first aspect of the invention, the at least one antenna comprises at least one feed antenna. Advantageously, complexity can be reduced, thereby increasing measurement efficiency.

According to a further preferred implementation form of the first aspect of the invention, the positioner comprises an elevation and/or a swing for the at least one rotational axis. Additionally or alternatively, the positioner comprises an additional outer axis, wherein the positioner comprises an elevation and/or a swing for the additional outer axis. Advantageously, flexibility, and thus also measurement efficiency can be increased.

According to a further preferred implementation form of the first aspect of the invention, the at least one rotational axis is arranged within an area directly below the device under test. Advantageously, for instance, complexity can be reduced, which leads to an increased measurement efficiency.

According to a further preferred implementation form of the first aspect of the invention, the at least one rotational axis comprises a locking mechanism. In addition to this or as an alternative, the common interface comprises a locking mechanism. Advantageously, for example, measurement efficiency can be increased.

According to a further preferred implementation form of the first aspect of the invention, the at least one rotational axis comprises a bayonet-type locking mechanism. Additionally or alternatively, the common interface comprises a bayonet-type locking mechanism. Advantageously, for instance, measurement efficiency can further be increased.

According to a further preferred implementation form of the first aspect of the invention, the different measurement setups comprise a measurement setup comprising a thermally isolated space, especially a thermal bubble, preferably with radio frequency neutral material. Advantageously, measurements under different temperature conditions can be performed in an efficient manner.

According to a further preferred implementation form of the first aspect of the invention, the different measurement setups comprise a measurement setup comprising head and/or hand phantoms. Advantageously, for instance, measurements with special respect to the specific absorption rate (SAR) of a device under test can be performed in an efficient and accurate manner.

According to a further preferred implementation form of the first aspect of the invention, the different measurement setups comprise a measurement setup comprising a heavy-weight device under test. Advantageously, the measurement system allows for performing measurements even with respect to a device under test of high weight.

According to a further preferred implementation form of the first aspect of the invention, the different measurement setups comprise a measurement setup comprising a base station. Advantageously, the measurement system allows for performing measurements even with respect to a device under test in the form of a base station or with respect to a base station in addition to a device under test.

According to a further preferred implementation form of the first aspect of the invention, the different measurement setups comprise a measurement setup comprising at least one device under test platform with at least one inlet and at least one outlet for warm or cool air. Advantageously, for instance, the device under test can be heated or cooled during measuring.

According to a further preferred implementation form of the first aspect of the invention, the material of the at least one device under test platform comprises foam, preferably rigid foam, more preferably rigid foam based on polymethacrylimide, most preferably rohacell. Advantageously, for example, said materials allow for highly accurate measurements especially due to their electromagnetic characteristics.

According to a further preferred implementation form of the first aspect of the invention, the different measurement setups comprise a measurement setup comprising a radar, preferably an automotive radar, with a worm gear driven tilt device. Advantageously, for instance, polarization can be synchronized in an accurate and efficient manner.

According to a further preferred implementation form of the first aspect of the invention, the worm gear driven tilt device uses the at least one rotational axis of the positioner. Advantageously, complexity can be reduced, thereby increasing measurement efficiency.

According to a further preferred implementation form of the first aspect of the invention, the at least one rotational axis comprises an inner rotational axis and an outer rotational axis. In this context, the common interface is arranged in a manner that the device under test is in the center of rotation of the outer rotational axis. Advantageously, for instance, the device under test can efficiently be rotated due to symmetry.

According to a further preferred implementation form of the first aspect of the invention, the at least one rotational axis comprises an inner rotational axis and an outer rotational axis. In this context, the common interface is arranged in a manner that the device under test is out of the center of rotation of the inner rotational axis. Advantageously, especially in the case that a compact antenna test range (CATR) reflector is used, this allows for an increased measurement accuracy.

According to a second aspect of the invention, a measurement method for over-the-air measurements is provided. The measurement method comprises the steps of positioning a device under test with the aid of a positioner comprising at least one rotational axis, and creating at least one electromagnetic wave along at least one vertical axis with respect to the device under test with the aid of at least one antenna connected to a measurement equipment. In this context, the at least one rotational axis comprises a common interface for different measurement setups. Advantageously, this allows for switching between different measurement setups in a highly efficient manner. Further advantageously, the measurement system can be used for both direct and indirect far-field systems, wherein the respective planar wave especially originates from above the device under test.

According to a first preferred implementation form of the second aspect of the invention, the at least one antenna comprises at least one feed antenna. Advantageously, complexity can be reduced, thereby increasing measurement efficiency.

According to a second preferred implementation form of the second aspect of the invention, the measurement method further comprises the step of arranging the at least one rotational axis within an area directly below the device under test. Advantageously, for instance, complexity can be reduced, which leads to an increased measurement efficiency.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and its several details can be modified in various obvious respects, all without departing from the spirit and scope of the present invention. Accordingly, the drawing and description are to be regarded as illustrative in nature, and not as restrictive.

### BRIEF DESCRIPTION OF THE DRAWINGS

Exemplary embodiments of the invention are now further explained by way of example only with respect to the drawings, in which:

FIG. 1 shows an exemplary embodiment of the first aspect of the invention;

FIG. 2 shows a second exemplary embodiment of the inventive system;

FIG. 3 shows a third exemplary embodiment of the inventive system;

FIG. 4 shows a fourth exemplary embodiment of the inventive system;

FIG. 5 shows a fifth exemplary embodiment of the inventive system;

FIG. 6 shows an exemplary embodiment of a positioner of the inventive system;

FIG. 7 shows the exemplary embodiment of the positioner of the inventive system with hand phantoms;

FIG. 8 shows the exemplary embodiment of the positioner of the inventive system with head and hand phantoms;

FIG. 9 shows an exemplary embodiment of an universal mount of the positioner;

FIG. 10 shows a side view of a second exemplary embodiment of an universal mount of the positioner;

FIG. 11 shows a three-dimensional view of the second exemplary embodiment of the universal mount of the positioner; and

FIG. 12 shows a flow chart of an exemplary embodiment of the second aspect of the invention.

### DETAILED DESCRIPTION

A measurement system and a corresponding measurement method for over-the-air measurements with special respect to switching between different measurement setups in a highly efficient manner due to an universal mount, are described. In the following description, for the purposes of explanation, numerous specific details are set forth in order to provide a thorough understanding of the invention. It is apparent, however, that the invention may be practiced without these specific details or with an equivalent arrangement. In other instances, well-known structures and devices are shown in block diagram form in order to avoid unnecessarily obscuring the invention.

A processor, unit, module or component (as referred to herein) may be composed of software component(s), which are stored in a memory or other computer-readable storage medium, and executed by one or more processors or CPUs of the respective devices. A module or unit may alternatively be composed of hardware component(s) or firmware component(s), or a combination of hardware, firmware and/or software components. Further, with respect to the various example embodiments described herein, while certain of the functions are described as being performed by certain components or modules (or combinations thereof), such descriptions are provided as examples and are thus not intended to be limiting. Accordingly, any such functions may be envisioned as being performed by other components or modules (or combinations thereof), without departing from the spirit and general scope of the present invention. Moreover, the methods, processes and approaches described herein may be processor-implemented using processing circuitry that may comprise one or more microprocessors, application specific integrated circuits (ASICs), field programmable gate arrays (FPGAs), or other devices operable to be configured or programmed to implement the systems and/or methods described herein. For implementation on such devices that are operable to execute software instructions, the flow diagrams and methods described herein may be implemented in processor instructions stored in a computer-readable medium, such as executable software stored in a computer memory store.

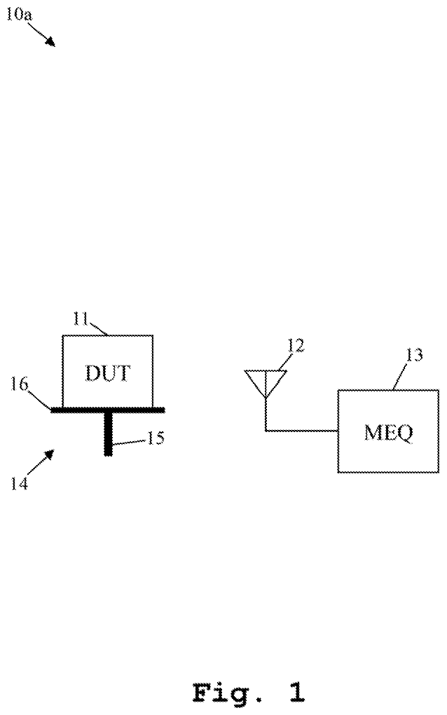

Firstly, FIG. 1 illustrates a first exemplary embodiment of the inventive measurement system 10a for over-the-air measurements. Said measurement system 10a comprises a device under test 11, an antenna 12, a measurement equipment 13 connected to the antenna 12, and a positioner 14 for positioning the device under test 11.

In this context, the positioner 14 comprises a rotational axis 15, and a common interface 16 for different measurement setups. In other words, the positioner 14 comprises an universal mount especially in the form of the common interface 16.

Furthermore, it is noted that the antenna 12 is especially adapted to create at least one electromagnetic wave along at least one vertical axis with respect to the device under test 11. In addition to this, the antenna 12 may preferably comprise or be a feed antenna.

Moreover, as it can be seen from FIG. 1, the rotational axis 15 is preferably arranged within an area directly below the device under test 11.

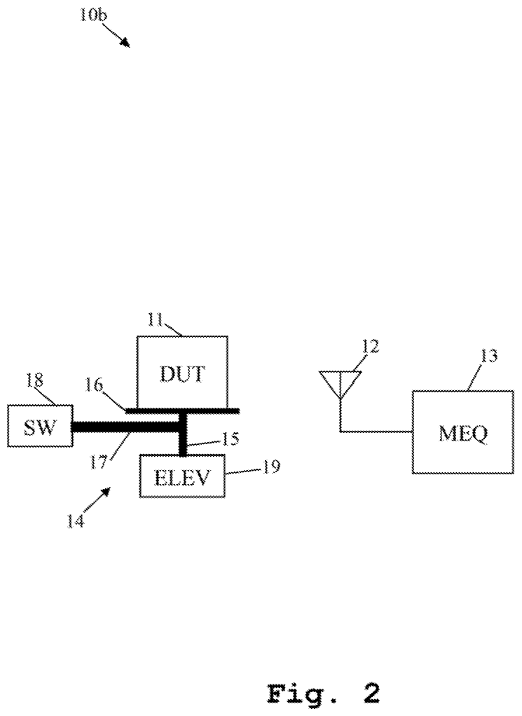

Now, with respect to FIG. 2, a second exemplary embodiment 10b of the inventive measurement system is shown. At this point, it is noted that parts being equipped with reference signs having already been discussed in the context of the foregoing figure are not explained again because it is referred to the respective points by the usage of the same reference signs. This analogously applies for each of the following figures.

As it can be seen from FIG. 2, the second exemplary embodiment 10b is based on the first exemplary embodiment 10a of FIG. 1, wherein the positioner 14 comprises an elevation for the rotational axis 15. In addition to this, the positioner 14 comprises an additional outer axis 17, wherein the positioner 14 comprises a swing 18 for the additional outer axis 17.

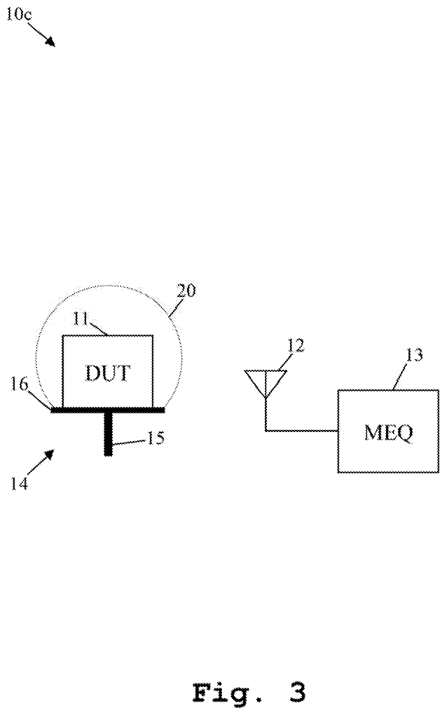

Furthermore, in accordance with FIG. 3, the measurement setup comprises a thermally isolated space, exemplarily a thermal bubble 20. Preferably, said thermal bubble 20 may comprise or may be made of radio frequency neutral material. Additionally, in this exemplary case, the thermal bubble 20 especially surrounds the device under test 11 and is preferably attached to the common interface 16.

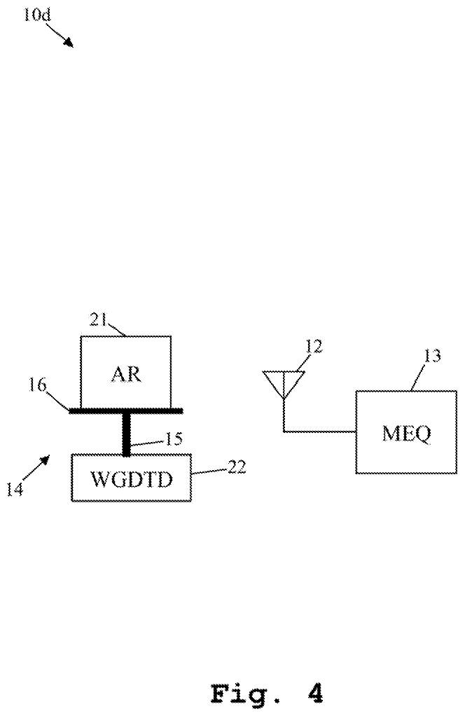

Moreover, FIG. 4 shows a measurement setup comprising a radar, exemplarily an automotive radar 21, with a worm gear driven tilt device 22. In this context, the worm gear driven tilt device 22 uses the rotational axis 15 of the positioner 14. As it can further he seen from FIG. 4, in this exemplary case, the automotive radar 21 is especially attached to the common interface 16.

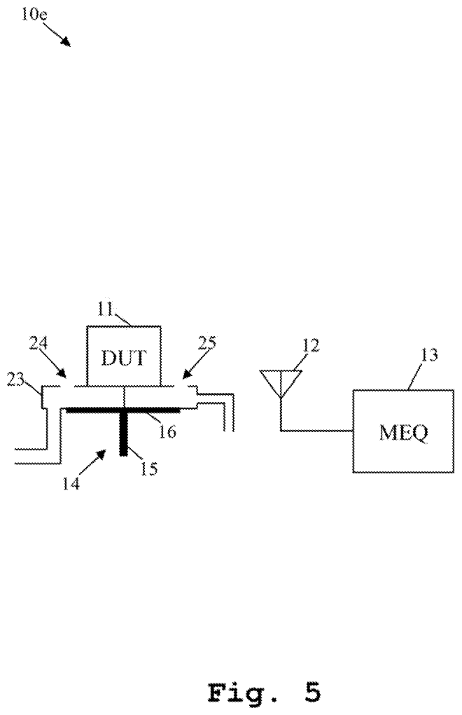

With respect to FIG. 5, a measurement setup is illustrated, which comprises a device under test platform 23 with an inlet 24 and an outlet 25 for warm or cool air.

In this context, it is noted that the material of the device under test platform 23 especially comprises foam, preferably rigid foam, more preferably rigid foam based on polymethacrylimide, most preferably rohacell. In addition to this, in this exemplary case, the device under test platform 23 is especially attached to the common interface 16.

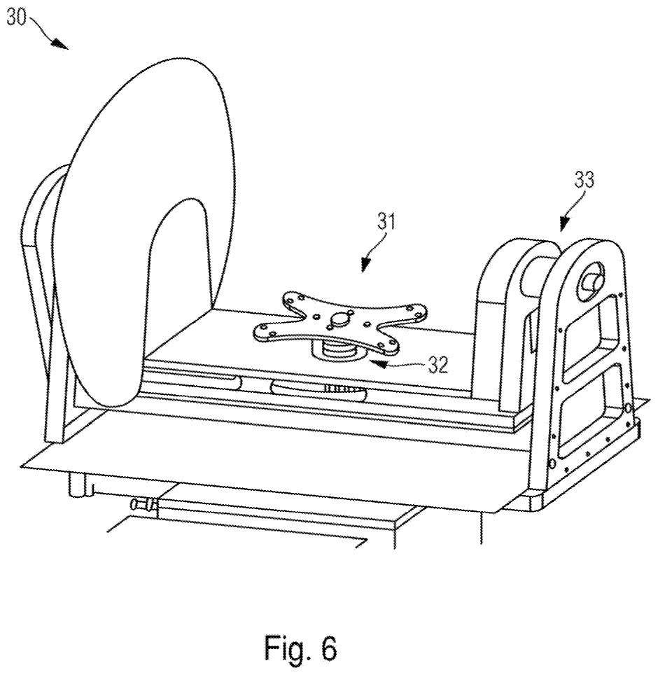

Furthermore, in accordance with FIG. 6, an exemplary embodiment of a positioner 30 of the inventive measurement system is shown. Said positioner 30 comprises an inner rotational axis 32, and a common interface 31 being especially attached to said inner rotational axis 32 for different measurement setups. In other words, the positioner 30 comprises an universal mount especially in the form of the common interface 31. In addition to this, as it can be seen from FIG. 6, the positioner 30 further comprises an outer rotational axis 33 especially for swinging the positioner 30.

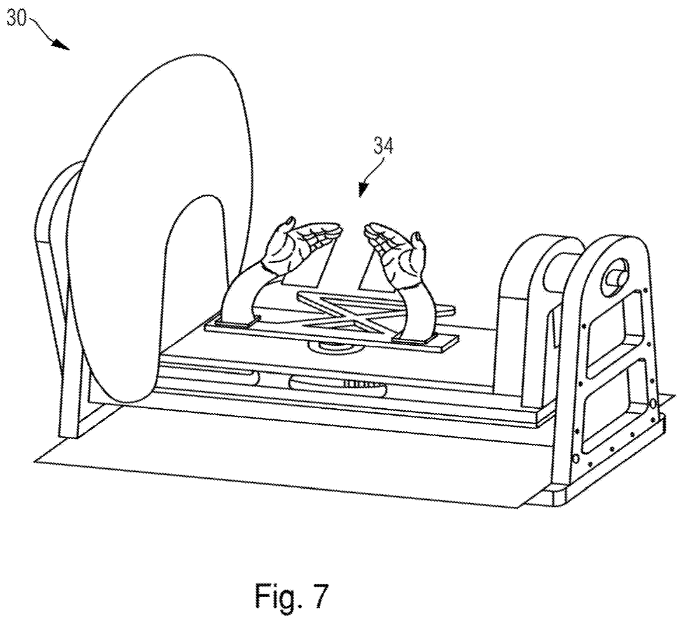

According to FIG. 7, a hand phantom 34 is attached to the common interface 31 of the positioner 30. In this context, said hand phantom 34 preferably comprises two hands being especially adapted to hold a tablet computer.

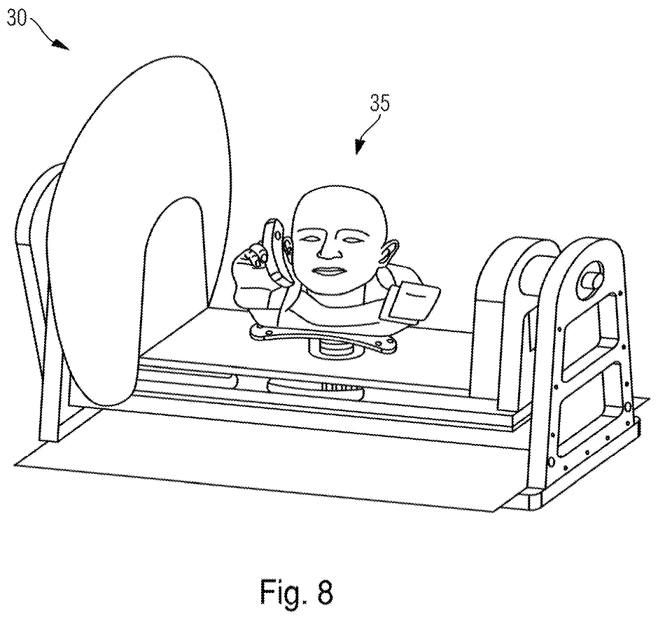

Moreover, in accordance with FIG. 8, a head and hand phantom 35 is attached to the common interface 31 of the positioner 30, In this context, said head and hand phantom 35 preferably comprises one hand being especially adapted to hold a mobile phone such as a phoning person.

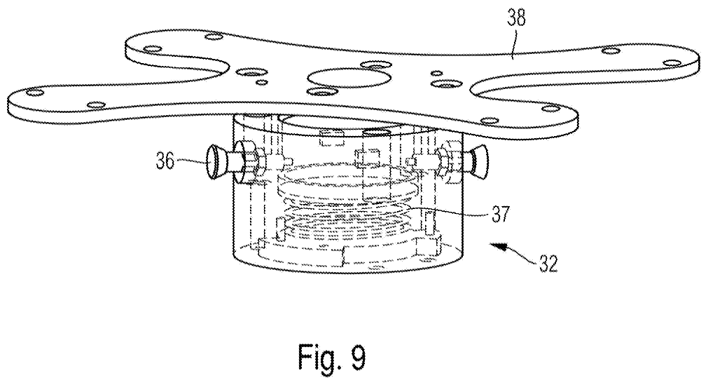

Now, with respect to FIG. 9, the common interface 31 of the positioner 30 is shown in more detail, In this exemplary embodiment, the common interface 31 comprises a platform, exemplarily a X-shaped platform 38 preferably with rounded edges, especially for mounting equipment with respect to different measurement setups. Additionally, it is noted that the platform 38 may especially be shaped like a metacentric chromosome.

As it can further be seen from FIG. 9, in this exemplary case, the common interface 31 is attached to a rotational axis 32 with the aid of a bayonet-type locking mechanism 36. In addition to this, a spring 37 is arranged in the region of the rotational axis 32 especially in order to hold the platform 38 in position,

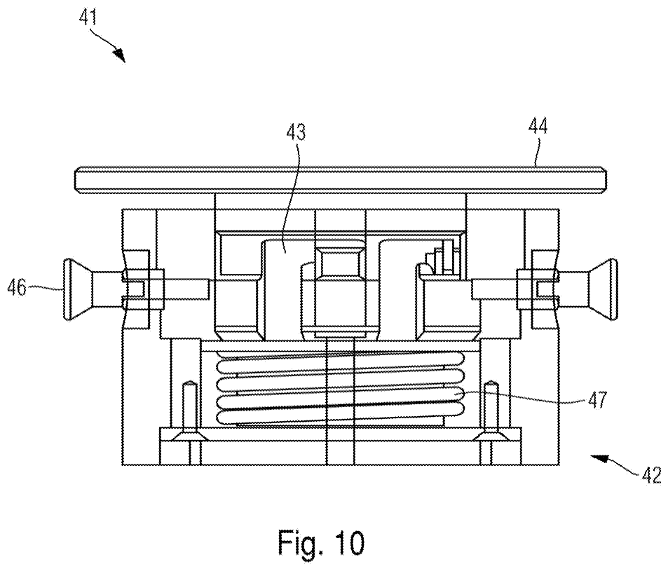

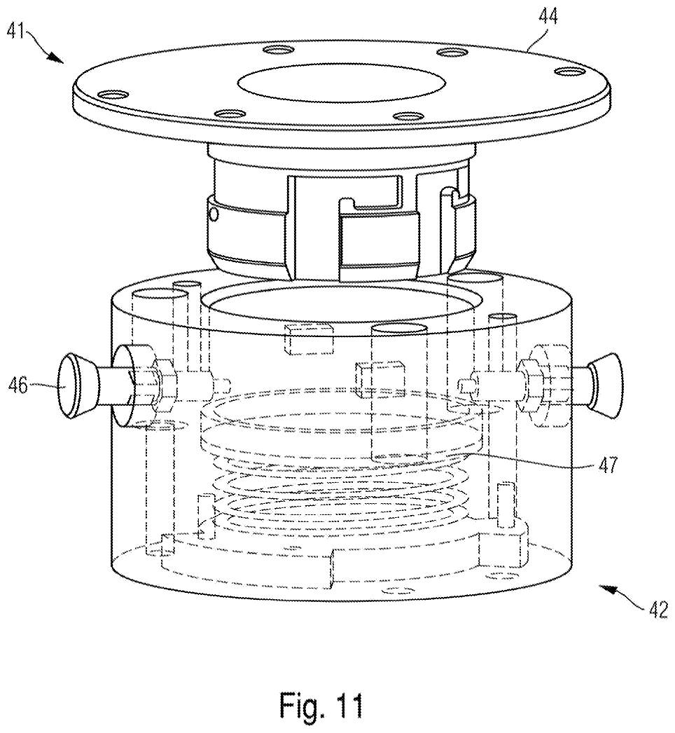

Furthermore, whereas FIG. 10 depicts a side view of a second exemplary embodiment of a common interface 41 of an inventive positioner such as the positioner 30, FIG. 11 illustrates a three-dimensional view of said second exemplary embodiment of the common interface 41.

In this context, with respect to this exemplary case, the common interface 41 comprises a platform, exemplarily a circularly-shaped platform 44, especially for mounting equipment with respect to different measurement setups.

Moreover, the common interface 41 is attached to a rotational axis 42 with the aid of a bayonet-type locking mechanism 46. In addition to this, a spring 47 is arranged in the region of the rotational axis 42 especially in order to hold the platform 44 in position. Further additionally, the common interface 41 comprises a slotted guide mechanism 43 especially for limiting the motion range of the platform 44 to a predefined range of values.

With respect to each of the above-described embodiments of the first aspect of the invention, it is noted that in the exemplary case that the rotational axis comprises an inner rotational axis and an outer rotational axis or an additional outer axis, respectively, the common interface may preferably be arranged in a manner that the device under test is in the center of rotation of the outer rotational axis or the additional outer axis, respectively.

In addition to this or as an alternative, the common interface may especially be arranged in a manner that the device under test is out of the center of rotation of the inner rotational axis.

Further additionally or further alternatively, the different measurement setups may comprise a measurement setup comprising a heavy-weight device under test.

In this context, further additionally or further alternatively, it is noted that the different measurement setups may comprise a measurement setup comprising a base station.

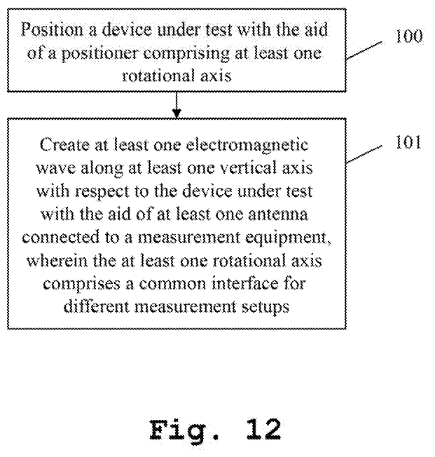

Finally, FIG. 12 shows a flow chart of an exemplary embodiment of the inventive measurement method for over-the-air measurements. In a first step 100, a device under test is positioned with the aid of a positioner comprising at least one rotational axis. Then, in a second step 101, at least one electromagnetic wave is created along at least one vertical axis with respect to the device under test with the aid of at least one antenna connected to a measurement equipment. In this context, the at least one rotational axis comprises a common interface for different measurement setups.

In addition to this, it is noted that the at least one antenna may preferably comprise at least one feed antenna.

Furthermore, the measurement method may further comprise the step of arranging the at least one rotational axis within an area directly below the device under test.

With respect to the positioner, it should be mentioned that the positioner may comprise an elevation and/or a swing for the at least one rotational axis. Additionally or alternatively, the positioner may comprise an additional outer axis, wherein the positioner may comprise an elevation and/or a swing for the additional outer axis.

In this context, it is noted that the measurement method may further comprise the step of elevating and/or swinging the at least one rotational axis. In addition to this, the measurement method may further comprise the step of elevating and/or swinging the additional outer axis.

Moreover, the at least one rotational axis may comprise a locking mechanism. In addition to this or as an alternative, the common interface may comprise a locking mechanism.

In this context, it is noted that the measurement method may further comprise the step of locking the at least one rotational axis with the aid of the locking mechanism. Additionally or alternatively, the measurement method may further comprise the step of locking the common interface with the aid of the locking mechanism.

It should further be mentioned that the at least one rotational axis may preferably comprise a bayonet-type locking mechanism. In addition to this or as an alternative, the common interface may preferably comprise a bayonet-type locking mechanism.

In this context, it is noted that the measurement method may further comprise the step of locking the at least one rotational axis with the aid of the bayonet-type locking mechanism. Additionally or alternatively, the measurement method may further comprise the step of locking the common interface with the aid of the bayonet-type locking mechanism.

Furthermore, with respect to the different measurement setups, it is noted that the different measurement setups may comprise a measurement setup comprising a thermally isolated space, especially a thermal bubble, preferably with radio frequency neutral material.

Additionally or alternatively, the different measurement setups may comprise a measurement setup comprising head and/or hand phantoms.

In further addition to this or as a further alternative, the different measurement setups may comprise a measurement setup comprising a heavy-weight device under test.

Further additionally or further alternatively, the different measurement setups may comprise a measurement setup comprising a base station.

Moreover, in addition to this or as an alternative, the different measurement setups may comprise a measurement setup comprising at least one device under test platform with at least one inlet and at least one outlet for warm or cool air.

In this context, the material of the at least one device under test platform may especially comprise foam, preferably rigid foam, more preferably rigid foam based on polymethacrylimide, most preferably rohacell.

In further addition to this or as a further alternative, the different measurement setups may comprise a measurement setup comprising a radar, preferably an automotive radar, with a worm gear driven tilt device.

In this context, it is noted that the worm gear driven tilt device may preferably use the at least one rotational axis of the positioner,

With special respect to the different measurement setups mentioned above, it is noted that the measurement method may further comprise the step of changing the measurement setup.

Moreover, in the exemplary case that the at least one rotational axis comprises an inner rotational axis and an outer rotational axis, the measurement method may preferably comprise the step of arranging the common interface in a manner that the device under test is in the center of rotation of the outer rotational axis.

In addition to this or as an alternative, also in the exemplary case that the at least one rotational axis comprises an inner rotational axis and an outer rotational axis, the measurement method may preferably comprise the step of arranging the common interface in a manner that the device under test is out of the center of rotation of the inner rotational axis.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

What is claimed is:

1. A measurement system for over-the-air measurements, the measurement system comprising:
a device under test;
at least one antenna;
a positioner for positioning the device under test, wherein the positioner comprises at least one rotational axis; and
a measurement equipment connected to the at least one antenna; and
wherein the at least one rotational axis comprises a common interface for different measurement setups.

2. The measurement system according to claim 1, wherein the at least one antenna is adapted to create at least one electromagnetic wave along at least one vertical axis with respect to the device under test.

3. The measurement system according to claim 1, wherein the at least one antenna comprises at least one feed antenna.

4. The measurement system according to claim 1, wherein one or more of the following conditions exist:
the positioner comprises one or more of an elevation and a swing for the at least one rotational axis; and
the positioner comprises an additional outer axis, wherein the positioner comprises one or more of an elevation and a swing for the additional outer axis.

5. The measurement system according to claim 1, wherein the at least one rotational axis is arranged within an area directly below the device under test.

6. The measurement system according to claim 1, wherein one or more of the at least one rotational axis and the common interface includes a locking mechanism.

7. The measurement system according to claim 6, wherein the locking mechanism is a bayonet-type locking mechanism.

8. The measurement system according to claim 1, wherein the different measurement setups comprise a measurement setup comprising one of a thermally isolated space, a thermal bubble, a thermally isolated space with radio frequency neutral material, and a thermal bubble with radio frequency neutral material.

9. The measurement system according to claim 1, wherein the different measurement setups comprise a measurement setup comprising one or more of head and hand phantoms.

10. The measurement system according to claim 1, wherein the different measurement setups comprise a measurement setup comprising a heavy-weight device under test.

11. The measurement system according to claim 1, wherein the different measurement setups comprise a measurement setup comprising a base station.

12. The measurement system according to claim 1, wherein the different measurement setups comprise a measurement setup comprising at least one device under test platform with at least one inlet and at least one outlet for warm or cool air.

13. The measurement system according to claim 12, wherein a material of the at least one device under test platform comprises one of foam, rigid foam, rigid foam based on polymethacrylimide, and rohacell.

14. The measurement system according to claim 1, wherein the different measurement setups comprise a measurement setup comprising one of a radar, an automotive radar, a radar with a worm gear driven tilt device, and an automotive radar with a worm gear driven tilt device.

15. The measurement system according to claim 14, wherein the worm gear driven tilt device uses the at least one rotational axis of the positioner.

16. The measurement system according to claim 1, wherein the at least one rotational axis comprises an inner rotational axis and an outer rotational axis, and wherein the common interface is arranged in a manner that the device under test is in the center of rotation of the outer rotational axis.

17. The measurement system according to claim 1, wherein the at least one rotational axis comprises an inner rotational axis and an outer rotational axis, and wherein the common interface is arranged in a manner that the device under test is out of the center of rotation of the inner rotational axis.

18. A measurement method for over-the-air measurements, the measurement method comprising the steps of:
positioning a device under test with the aid of a positioner comprising at least one rotational axis; and
creating at least one electromagnetic wave along at least one vertical axis with respect to the device under test with the aid of at least one antenna connected to a measurement equipment; and
wherein the at least one rotational axis comprises a common interface for different measurement setups.

19. The measurement method according to claim 18, wherein the at least one antenna comprises at least one feed antenna.

20. The measurement method according to claim 18, wherein the measurement method further comprises the step of:
arranging the at least one rotational axis within an area directly below the device under test.
